(19) United States
(12) Patent Application Publication
(10) Pub. No.: US 2025/0081576 A1
(43) Pub. Date: Mar. 6, 2025

(54) SEMICONDUCTOR DEVICE AND METHOD FOR MANUFACTURING THE SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Tsuyoshi KACHI, Kanazawa Ishikawa (JP)

(21) Appl. No.: 18/587,861

(22) Filed: Feb. 26, 2024

(30) Foreign Application Priority Data
Sep. 5, 2023 (JP) 2023-143989

(51) Int. Cl. H01L 29/40; H01L 29/06; H01L 29/66; H01L 29/78

(52) U.S. Cl. CPC H10D 64/112; H10D 30/0297; H10D 30/668; H10D 62/109; H10D 62/127; H10D 64/117

(57) ABSTRACT

A semiconductor device includes a first electrode, a first semiconductor region of a first type including first and second regions, second semiconductor regions of a second type on the first region, third semiconductor regions of the first type on the second semiconductor regions, a second electrode electrically connected to the third semiconductor regions, first structures in the first region, each of which includes an insulating region and a conductive region, second structures in the second region, each of which includes an insulating region and a conductive region, a third electrode surrounding the first and second structures, a first insulating portion between the second semiconductor region and the third electrode, a second insulating portion above the second region, and a wiring portion above the second insulating portion and electrically connected to the third electrode.

### CROSS-REFERENCE TO RELATED APPLICATION

This application is based upon and claims the benefit of priority from the Japanese Patent Application No. 2023-143989, filed on Sep. 5, 2023, the entire contents of which are incorporated herein by reference.

### FIELD

Embodiments described herein relate generally to a semiconductor device and a method for manufacturing the semiconductor device.

### BACKGROUND

Semiconductor devices, such as MOSFETs (Metal Oxide Semiconductor Field Effect Transistors), are used for power conversion and other applications. It is preferable that on-resistance of semiconductor devices is low.

### BRIEF DESCRIPTION OF THE DRAWINGS

FIG. 1 is a top view of a semiconductor device according to a first embodiment.

FIG. 2 is a top view of a portion of the semiconductor device according to the first embodiment.

FIG. 3 is a cross-sectional diagram of the semiconductor device according to the first embodiment.

FIG. 4 is a cross-sectional diagram of the semiconductor device according to the first embodiment.

FIG. 5 is a cross-sectional diagram of the semiconductor device according to the first embodiment.

FIG. 6 is a cross-sectional diagram of the semiconductor device according to the first embodiment.

FIG. 7 is a cross-sectional diagram of a semiconductor device according to a second embodiment.

FIGS. 8A to 8E are cross-sectional diagrams illustrating a method for manufacturing a semiconductor device according to an embodiment.

FIGS. 9A to 9E are cross-sectional diagrams illustrating the method for manufacturing the semiconductor device according to the embodiment.

### DETAILED DESCRIPTION

Embodiments provide a semiconductor device and a method for manufacturing a semiconductor device having reduced on-resistance.

In general, according to one embodiment, a semiconductor device comprises a first electrode, a first semiconductor region of a first type above the first electrode, the first semiconductor region including first and second regions, a plurality of second semiconductor regions of a second type on the first region, a plurality of third semiconductor regions of the first type on the second semiconductor regions, a second electrode above the third semiconductor regions and electrically connected to the third semiconductor regions, a plurality of first structures in the first region and surrounded by the second and third semiconductor regions, each of the first structures including a first insulating region and a first conductive region inside the first insulating region, the first structures being arranged in a second direction perpendicular to a first direction from the first electrode toward the second electrode and in a third direction perpendicular to the first and second directions, a plurality of second structures in the second region, each of the second structures including a second insulating region and a second conductive region inside the second insulating region, the second structures being arranged in the second and third directions, a third electrode surrounding the first and second structures and extending along the second and third directions, a first insulating portion between the second semiconductor region and the third electrode, a second insulating portion above the second region, and a wiring portion above the second insulating portion and electrically connected to the third electrode.

Hereinafter, certain example embodiments according to the present disclosure will be described with reference to the drawings.

Further, the drawings are drawn schematically and conceptually, a relation between thickness and width of each component and a ratio between sizes of the components are not necessarily the same as in an actual component. In addition, the dimensions and ratios of the same component may be differently illustrated depending on the drawings.

In addition, in the specification and the drawings, an identical reference symbol is allotted to aspects previously described in relation to a previously described drawing or the like, the descriptions of repeated elements will be omitted as appropriate.

In the following description and the drawings, the denotation of n+, n−, p+, and p− indicates a relative magnitude of an impurity concentration for each conductive type. In other words, a type attached with the denotation of “+” means that the type has an impurity concentration relatively higher than that of other types. A type attached with the denotation of “−” means that the type has an impurity concentration relatively lower than that of other types. When each region contains both a p type impurity and an n type impurity, these denotations represent a relative level of a net impurity concentration after these impurities compensate for each other.

For each embodiment described below, the p type and n type of each semiconductor region may be switched.

### First Embodiment

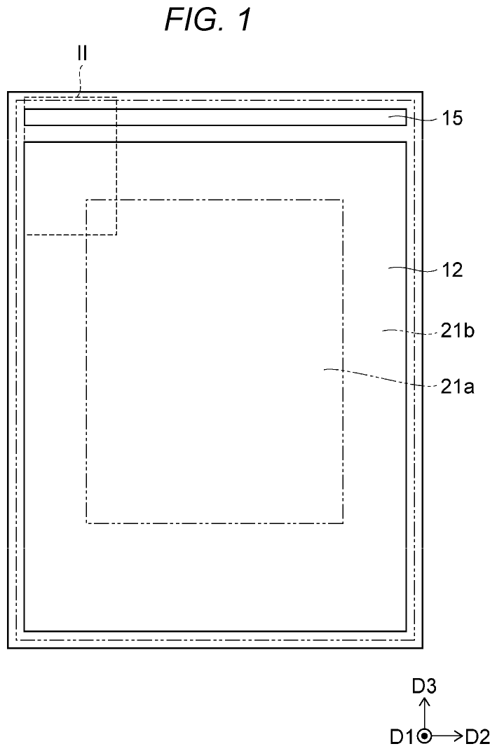

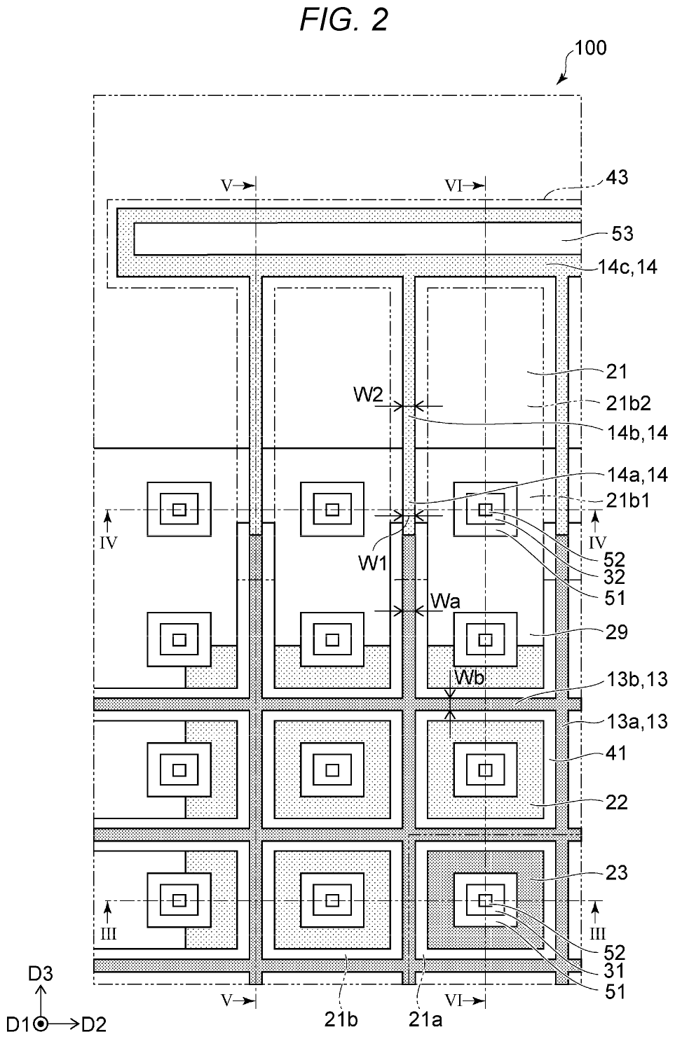

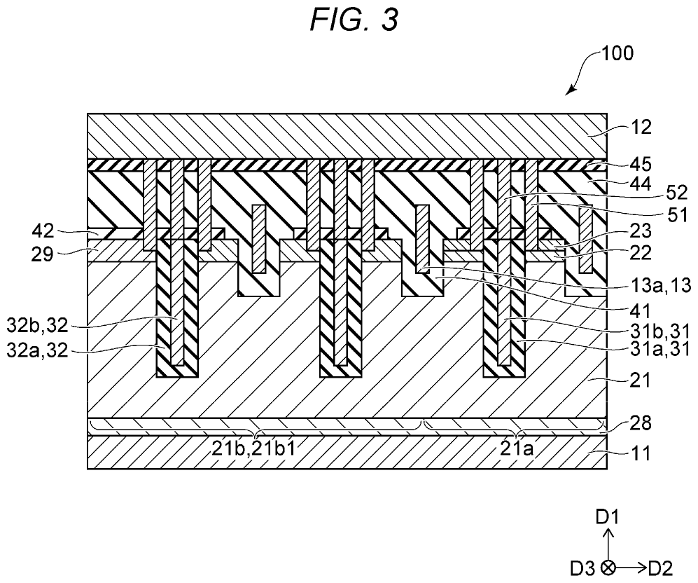

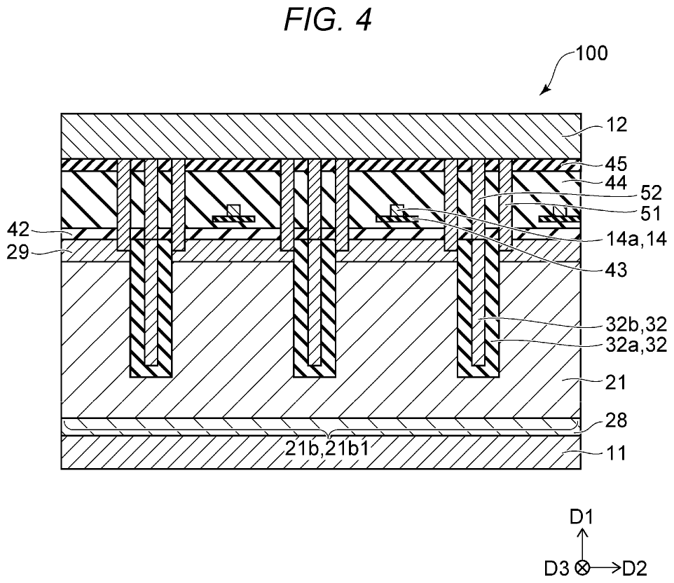

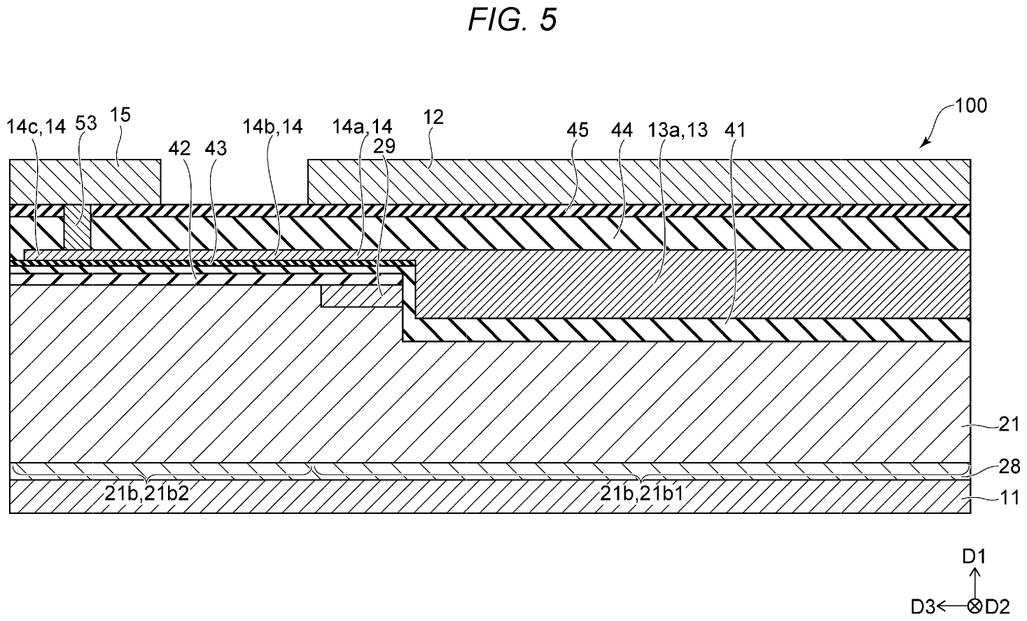

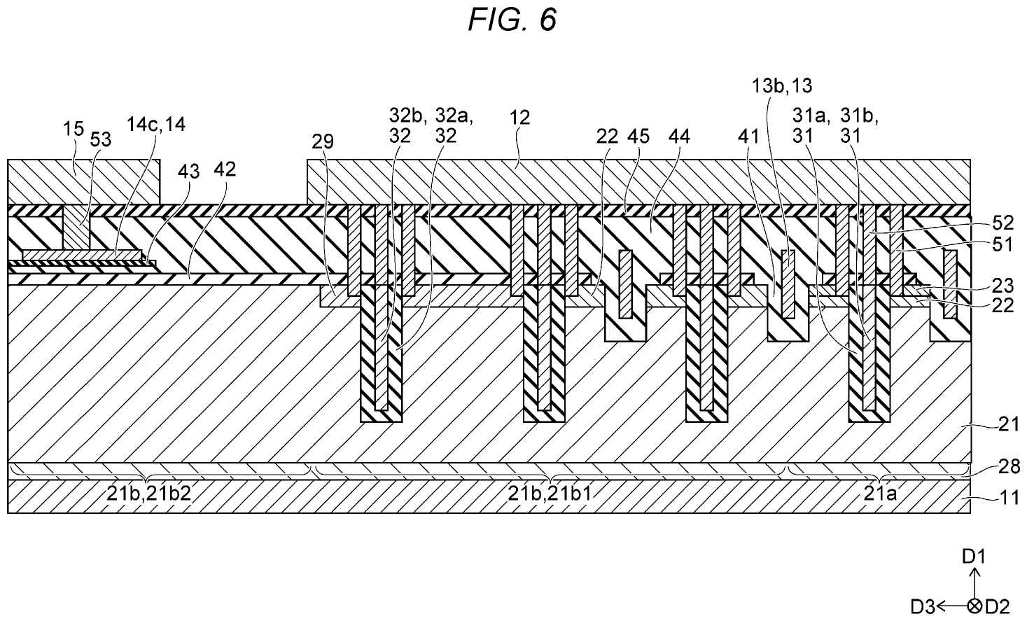

A semiconductor device 100 according to a first embodiment is a vertical MOSFET. The semiconductor device 100 is a MOSFET having a so-called dot FP (field plate) structure. FIG. 1 is a top view diagram of the semiconductor device 100. FIG. 2 is an enlarged view of a region II illustrated in FIG. 1. FIG. 3 is a cross-sectional diagram taken in a line III-III illustrated in FIG. 2. FIG. 4 is a cross-sectional diagram taken in a line IV-IV illustrated in FIG. 2. FIG. 5 is a cross-sectional diagram taken in a line V-V illustrated in FIG. 2. FIG. 6 is a cross-sectional diagram taken in a line VI-VI illustrated in FIG. 2.

As illustrated in FIGS. 1 to 6, the semiconductor device 100 includes a drain electrode 11, a source electrode 12, a gate electrode 13, a wiring portion 14, a gate pad 15, an n-type drift region 21, a p type base region 22, an n+ type source region 23, an n+ type drain region 28, a reduced surface field (RESURF) region 29, a first structure 31, a second structure 32, a gate insulating portion 41, a field oxide film 42, an etch stopper film 43, a first interlayer insulating film 44, a second interlayer insulating film 45, a first connection portion 51, a second connection portion 52, and a third connection portion 53. In the semiconductor device 100, the first conductivity type is an n type and the second conductivity type is a p type. The source electrode 12 and the gate pad 15 are not shown in FIG. 2.

In the following description of each embodiment, a first direction D1, a second direction D2, and a third direction D3 are used. The direction from the drain electrode 11 toward the source electrode 12 is referred to as the first direction D1. One of the directions perpendicular to the first direction D1 is referred to as the second direction D2. The direction perpendicular to the first direction D1 and the second direction D2 is referred to as the third direction D3. In addition, for the sake of clarity of explanation, the side of the source electrode 12 in the first direction D1 is referred to as “above”, and the opposite side is referred to as “below”, but these directions are not necessarily related to a direction of gravity. A view from above provides a planar view.

As illustrated in FIG. 1, the source electrode 12 and the gate pad 15 are disposed on an upper surface of the semiconductor device 100. The source electrode 12 and the gate pad 15 are electrically separated from each other.

As illustrated in FIGS. 3 to 6, the drain electrode 11 is disposed on a lower surface of the semiconductor device 100. On the drain electrode 11, the n-type drift region 21 is disposed with the n+ type drain region 28 interposed therebetween. The n-type drift region 21 is electrically connected to the drain electrode 11 via the n+ type drain region 28. The n-type drift region 21 includes a first region 21a and a second region 21b. The second region 21b is disposed around the first region 21a. The first region 21a is located at a center of the n-type drift region 21 in planar view. The second region 21b is located at an outer periphery of the n-type drift region 21 in planar view. The p type base region 22 is disposed on the first region 21a of the n-type drift region 21. On the p type base region 22, the n+ type source region 23 is selectively disposed. The p type base region 22 and the n+ type source region 23 are electrically connected to the source electrode 12 via the first connection portion 51.

A plurality of first structures 31 are disposed in the first region 21a. Each of the first structures 31 includes a first insulating region 31a and a first conductive region 31b. The first insulating region 31a is aligned with the first region 21a in the second direction D2 and the third direction D3. The first conductive region 31b is disposed inside the first insulating region 31a. The first insulating region 31a is located between the first conductive region 31b and the first region 21a in the second direction D2 and the third direction D3. Moreover, a portion of the first insulating region 31a is located between the first conductive region 31b and the first region 21a in the first direction. Thus, the first conductive region 31b is surrounded by the first insulating region 31a. The first conductive region 31b is electrically connected to the source electrode 12 via the second connection portion 52. The first conductive region 31b functions as an FP electrode. The first insulating region 31a functions as an FP insulating portion.

A plurality of second structures 32 are disposed in the second region 21b. Each of the second structures 32 includes a second insulating region 32a and a second conductive region 32b. The second insulating region 32a is aligned with the second region 21b in the second direction D2 and the third direction D3. The second conductive region 32b is disposed inside the second insulating region 32a. The second insulating region 32a is located between the second conductive region 32b and the second region 21b in the second direction D2 and the third direction D3. Moreover, a portion of the second insulating region 32a is located between the second conductive region 32b and the second region 21b in the first direction. Thus, the second conductive region 32b is surrounded by the second insulating region 32a. The second conductive region 32b is electrically connected to the source electrode 12 via the second connection portion 52. The second conductive region 32b functions as an FP electrode. The second insulating region 32a functions as an FP insulating portion.

In the semiconductor device 100, the first structures 31 and the second structures 32 are arranged along the second direction D2 and the third direction D3. The first structures 31 and the second structures 32 are disposed in a quadrangular shape in planar view. The first structures 31 and the second structures 32 may be disposed, for example, in an equilateral triangular shape in planar view.

The gate electrode 13 surrounds the first structures 31 and the second structures 32 in the second direction D2 and the third direction D3. The gate electrode 13 is disposed between the first structures 31 and the second structures 32 in the second direction D2 and the third direction D3. In the semiconductor device 100, the gate electrode 13 includes a first gate region 13a and a second gate region 13b. The first gate region 13a extends along the third direction D3. The second gate region 13b extends along the second direction D2. Each of the first structures 31 is disposed between a pair of the first gate regions 13a and between a pair of the second gate regions 13b. Some of the second structures 32 are each disposed between a pair of the first gate regions 13a and between a pair of the second gate regions 13b.

The gate electrode 13 is aligned with the p type base region 22 in the second direction D2 and the third direction D3. In the semiconductor device 100, a portion of the gate electrodes 13 is aligned with a portion of the n-type drift region 21 in the second direction D2 and the third direction D3. In the semiconductor device 100, a portion of the gate electrodes 13 is aligned with the n+ type source region 23 in the second direction D2 and the third direction D3.

The gate insulating portion 41 is disposed between the gate electrode 13 and the p type base region 22 in the second direction D2 and the third direction D3. In the semiconductor device 100, a portion of the gate insulating portion 41 is disposed between the gate electrode 13 and the n-type drift region 21 in the second direction D2 and the third direction D3. A portion of the gate insulating portion 41 is disposed between the gate electrode 13 and the n+ type source region 23 in the second direction D2 and the third direction D3. Thus, the gate electrode 13 is surrounded by the gate insulating portion 41. The gate electrode 13 is disposed inside the gate insulating portion 41.

The RESURF region 29 is disposed on a portion of the second region 21b of the n-type drift region 21. The field oxide film 42 is disposed on the second region 21b, the RESURF region 29, the p type base region 22, and the n+ type source region 23. The first interlayer insulating film 44 is disposed on the field oxide film 42. The second interlayer insulating film 45 is disposed on the first interlayer insulating film 44. The source electrode 12 is disposed on a portion of the second interlayer insulating film 45. The gate pad 15 is disposed on another portion of the second interlayer insulating film 45. Moreover, a wiring portion 14 is disposed on a portion of the field oxide film 42. The wiring portion 14 is electrically connected to the gate electrode 13. In the semiconductor device 100, the etch stopper film 43 is disposed under the wiring portion 14. The etch stopper film 43 may not be disposed. The second region 21b includes a first portion 21b1 and a second portion 21b2. The first portion 21b1 is aligned with the second structures 32 in the second direction D2. The first portion 21b1 is a portion of the second region 21b where the second structure 32 is disposed. The second portion 21b2 is disposed around the first portion 21b1. The second portion 21b2 is a portion of the second regions 21b where no second structure 32 is disposed.

The wiring portion 14 includes a plurality of first wiring regions 14a, a plurality of second wiring regions 14b, and a third wiring region 14c. The first wiring regions 14a are disposed on the first portion 21b1. The second wiring regions 14b and the third wiring region 14c are disposed on the second portion 21b2. The first wiring regions 14a and the second wiring regions 14b extend along the third direction D3. The third wiring region 14c extends along the second direction D2. The first wiring regions 14a connect the gate electrode 13 (the first gate region 13a) to the second wiring region 14b. The second wiring regions 14b connect the first wiring region 14a to the third wiring region 14c. The third wiring region 14c is connected to the gate pad 15 via the third connection portion 53. Accordingly, the gate electrode 13 is electrically connected to the gate pad 15 via the wiring portion 14 and the third connection portion 53. The gate pad 15 is electrically separated from the source electrode 12.

As illustrated in FIG. 2, a width W1 of the first wiring region 14a is the same as a width Wa of the gate electrode 13. The width W1 is a width in the second direction D2 of the first wiring region 14a. The width Wa is a width in the second direction D2 of a portion of the gate electrode 13 (the first gate region 13a) extending along the third direction D3. Moreover, in the semiconductor device 100, a width W2 of the second wiring region 14b is the same as the width W1. The width W2 is a width in the second direction D2 of the second wiring region 14b. The width W2 may be larger or smaller than the width W1. Moreover, in the semiconductor device 100, the width Wa in the second direction D2 of the portion of the gate electrode 13 (the first gate region 13a) extending along the third direction D3 is the same as a width Wb in the third direction D3 of a portion of the gate electrode 13 (the second gate region 13b) extending along the second direction D2.

As illustrated in FIG. 5, in the semiconductor device 100, an upper edge of the gate electrode 13 is aligned with an upper edge of the wiring portion 14 in the third direction D3. More specifically, in the semiconductor device 100, the upper edge of the gate electrode 13 is aligned with an upper edge of the first wiring region 14a, an upper edge of the second wiring region 14b, and an upper edge of the third wiring region 14c in the third direction D3. The upper edge of the gate electrode 13 is located above an upper edge of the n-type drift region 21, an upper edge of the p type base region 22, and an upper edge of the n+ type source region 23. Moreover, the upper edge of the gate electrode 13 in an element region is located above an upper edge of the field oxide film 42.

Moreover, in the semiconductor device 100, a lower edge of the gate electrode 13 is located below a lower edge of the wiring portion 14. More specifically, in the semiconductor device 100, the lower edge of the gate electrode 13 is located below a lower edge of the first wiring region 14a, a lower edge of the second wiring region 14b, and a lower edge of the third wiring region 14c.

As illustrated in FIG. 2, in the semiconductor device 100, a shape of the first structure 31 and the second structure 32 in planar view is quadrilateral. The shape of the first structure 31 and the second structure 32 in planar view may be, for example, triangular, hexagonal, circular, or the like. Moreover, in the case of polygon, vertices may be rounded.

An operation of the semiconductor device 100 will be described.

In a state where a positive voltage is applied to the drain electrode 11 with respect to the source electrode 12, a voltage greater than a threshold value is applied to the gate electrode 13. Consequently, a channel (or an inversion layer) is formed in the p type base region 22, and the semiconductor device 100 is turned to an ON state. Electrons flow through the channel from the source electrode 12 to the drain electrode 11. Then, when the voltage applied to the gate electrode 13 becomes lower than the threshold value, the channel in the p type base region 22 disappears, and the semiconductor device 100 is turned to an OFF state.

When the semiconductor device 100 is turned to the OFF state, the positive voltage applied to the drain electrode 11 with respect to the source electrode 12 increases. More specifically, a potential difference between the n-type drift region 21 and the FP electrode (the first conductive region 31b or the second conductive region 32b) increases. Due to the increase in the potential difference, a depletion layer widens from an interface between the FP insulating portion (the first insulating region 31a or the second insulating region 32a) and the n-type drift region 21 toward the n-type drift region 21. Since the depletion layer is widened, a breakdown voltage of the semiconductor device 100 can be improved. Alternatively, a concentration of an impurity which is a donor in the n-type drift region 21 can be increased while the breakdown voltage of the semiconductor device 100 is maintained, and thereby the on-resistance of the semiconductor device 100 can be reduced.

Examples of materials of each component of the semiconductor device 100 will be described.

Each of the drain electrode 11, the source electrode 12, and the gate pad 15 comprises a metal, such as aluminum or copper.

Each of the n-type drift region 21, the p type base region 22, the n+ type source region 23, the n+ type drain region 28, and the RESURF region 29 comprises silicon, silicon carbide, gallium nitride, or gallium arsenide, as a semiconducting material. When silicon is used as the semiconducting material, arsenic, phosphorus, or antimony can be used as an impurity which is a donor. Boron can be used as an impurity serving as an acceptor.

Each of the gate electrode 13, the first conductive region 31b, and the second conductive region 32b comprises a conductive material, such as polysilicon. Impurities may be added to the conductive material.

Each of the gate insulating portion 41, the field oxide film 42, the etch stopper film 43, the first interlayer insulating film 44, and the second interlayer insulating film 45 comprises an insulating material. The gate insulating portion 41, the field oxide film 42, the etch stopper film 43, the first interlayer insulating film 44, and the second interlayer insulating film 45 comprise, for example, a silicon oxide or a silicon nitride.

Each of the first connection portion 51, the second connection portion 52, and the third connection portion 53 comprises a metal, such as tungsten, aluminum, or copper.

In the semiconductor device 100 according to the first embodiment, a plurality of first structures 31 and a plurality of second structures 32 which function as FP electrodes are disposed in the second direction D2 and the third direction D3. According to such a structure, a volume of the n-type drift region 21 serving as a current path can be increased compared with a case where the first structures 31 and the second structures 32 continuously extend in a single direction. Consequently, the on-resistance of the semiconductor device 100 can be reduced. In addition, in the semiconductor device 100, a gate electrode 13 is disposed so as to surround the first structures 31 and the second structures 32 in the second direction D2 and the third direction D3. According to such a structure, channels are formed in more regions compared with a case where the gate electrode 13 continuously extends in a single direction. Accordingly, a channel density is improved and the on-resistance of the semiconductor device 100 is further decreased. For example, when the on-resistance of the semiconductor device 100 is decreased, a density of current flowing through the semiconductor device 100 can be improved. Due to the improvement in the current density, it is possible to miniaturize the semiconductor device 100. Alternatively, the number of the semiconductor devices 100 required for flowing a predetermined current can be reduced.

On the other hand, in a case of providing the wiring portion 14 for connecting the gate electrode 13 to the gate pad 15 between the second structures 32 in planar view, when the width of the wiring portion 14 is increased, there is a concern that a distance between the wiring portion 14 and the first connection portion 51 which is connected to the source electrode 12 becomes smaller, and an insulating breakdown voltage between the gate electrode 13 and the source electrode 12 decreases. In contrast, when the distance between the wiring portion 14 and the first connection portion 51 which is connected to the source electrode 12 is increased so that the insulating breakdown voltage between the gate electrode 13 and the source electrode 12 may not decrease, a pitch between the plurality of second structures 32 may be wider.

In the semiconductor device 100, the width W1 of the first wiring region 14a located between the second structures 32 in planar view is the same as the width Wa of the gate electrode 13. Consequently, the pitch between the second structures 32 can be narrowed. Accordingly, the channel density can be improved and the on-resistance of the semiconductor device 100 can be reduced.

In addition, in the semiconductor device 100, the upper edge of the gate electrode 13 is aligned with the upper edge of the wiring portion 14 in the third direction D3. Accordingly, the gate electrode 13 and the wiring portion 14 can be formed in a single chemical mechanical polishing (CMP) process. In addition, since the upper edge of the gate electrode 13 is flush, and a volume can be secured by a height of the gate electrode 13 even when the width of the gate electrode 13 is decreased, a gate resistance can be reduced.

Moreover, in the semiconductor device 100, the upper edge of the gate electrode 13 in the element region is located above the upper edge of the field oxide film 42. Accordingly, the volume can be secured by the height of the gate electrode 13 even when the width of the gate electrode 13 is decreased, a gate resistance can be reduced.

In addition, in the semiconductor device 100, the etch stopper film 43 is disposed below the wiring portion 14. Accordingly, an insulating breakdown voltage between the gate electrode 13 and the drain electrode 11 can be improved.

### Second Embodiment

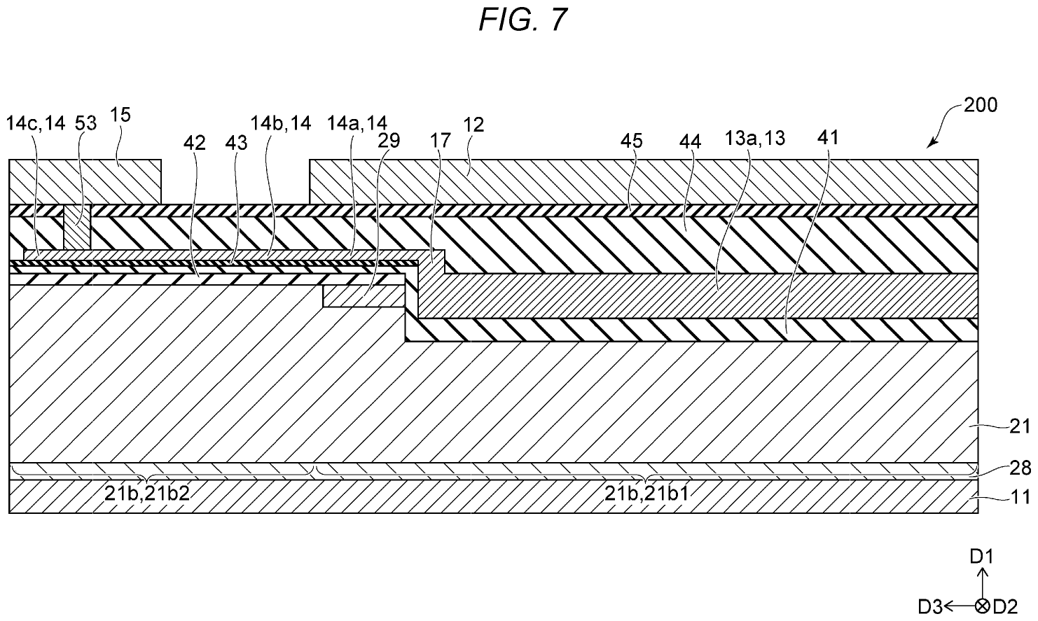

FIG. 7 is a cross-sectional diagram of a semiconductor device 200 according to a second embodiment. FIG. 7 is a cross-sectional diagram corresponding to FIG. 5. As illustrated in FIG. 7, the semiconductor device 200 is different from the semiconductor device 100 in the location of the upper edge of the gate electrode 13. The rest of structure is the same as that of the semiconductor device 100.

In the semiconductor device 200, the upper edge of the gate electrode 13 is located below the upper edge of the wiring portion 14. More specifically, in the semiconductor device 200, the upper edge of the gate electrode 13 is located below the upper edge of the first wiring region 14a, the upper edge of the second wiring region 14b, and the upper edge of the third wiring region 14c. In the semiconductor device 200, the upper edge of the gate electrode 13 is aligned with the upper edge of the field oxide film 42 in the third direction D3.

In addition, in the semiconductor device 200, the lower edge of the wiring portion 14 is located above the upper edge of the gate electrode 13. In other words, in the semiconductor device 200, the wiring portion 14 is not aligned with the gate electrode 13 in the third direction D3. The wiring portion 14 is connected to the gate electrode 13 via an upward extending portion 17 extending along the first direction D1.

### (Manufacturing Method)

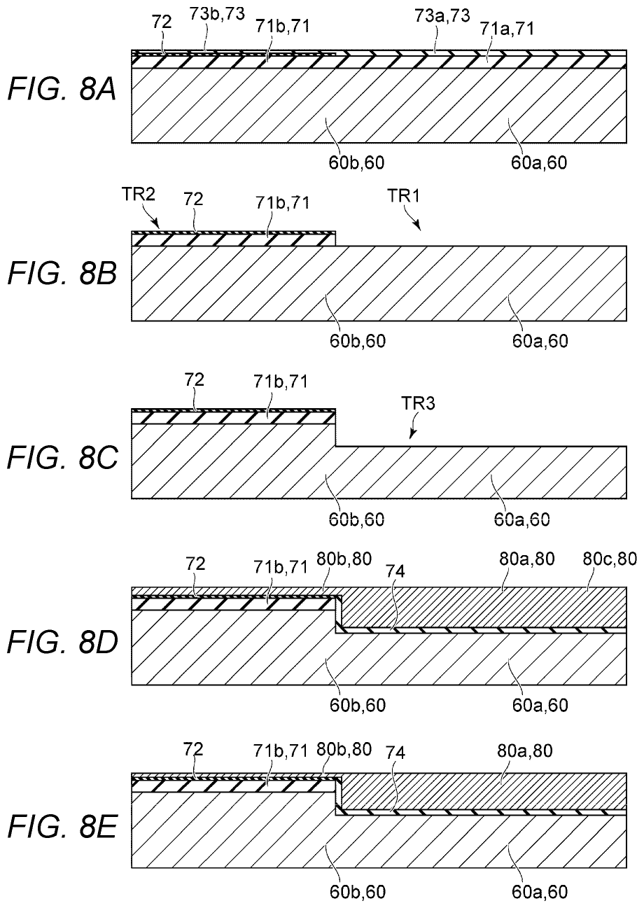

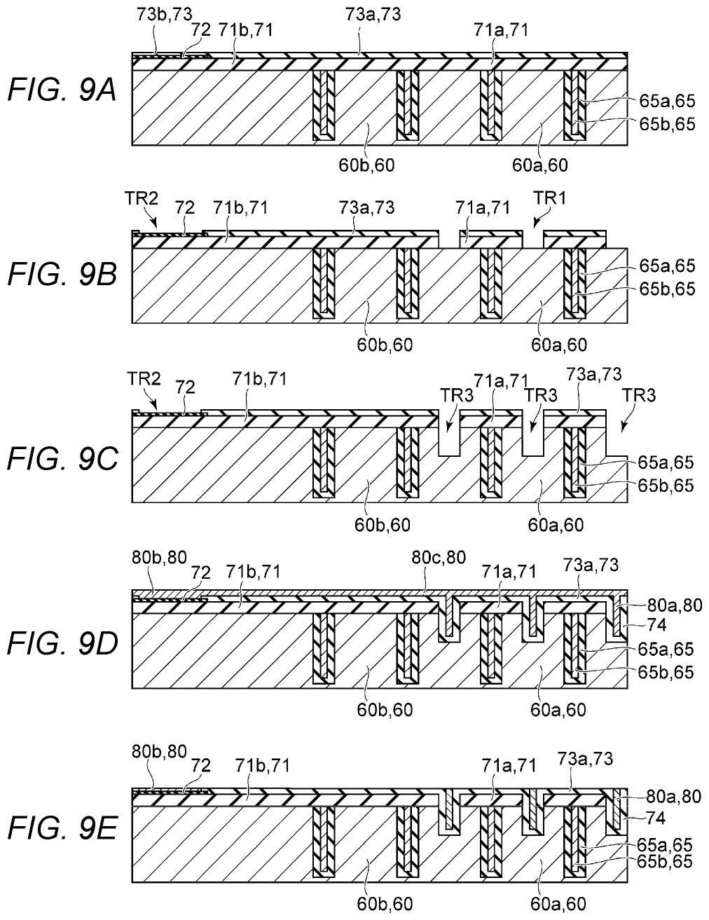

FIGS. 8A to 8E and FIGS. 9A to 9E are cross-sectional diagrams for illustrating a method for manufacturing a semiconductor device according to an embodiment. FIGS. 8A to 8E are cross-sectional diagrams corresponding to FIG. 5. FIGS. 9A to 9E are cross-sectional diagrams corresponding to FIG. 6. As illustrated in FIGS. 8A to 8E and FIGS. 9A to 9E, the method includes a first step, a second step, a third step, a fourth step, a fifth step, a sixth step, a seventh step, and an eighth step.

FIGS. 8A and 9A correspond to the first step, the second step, and the third step. FIGS. 8B and 9B correspond to the fourth step. FIGS. 8C and 9C correspond to the fifth step. FIGS. 8D and 9D correspond to the sixth step and the seventh step. FIGS. 8E and 9E correspond to the eighth step. Hereinafter, each step will be described.

In the first step, as illustrated in FIGS. 8A and 9A, a first insulating layer 71 is formed on a semiconductor region 60. The semiconductor region 60 includes a first region 60a and a second region 60b. The second region 60b is located around the first region 60a. A plurality of structures 65 is disposed inside the semiconductor region 60. Each of the structures 65 includes an insulating region 65a and a conductive region 65b. The conductive region 65b is disposed inside the insulating region 65a. The first insulating layer 71 includes a first insulating layer region 71a and a second insulating layer region 71b. The first insulating layer region 71a overlaps the first region 60a. The second insulating layer region 71b overlaps the second region 60b. The first insulating layer 71 is formed by, for example, Chemical Vapor Deposition (CVD) or the like. The semiconductor region 60 corresponds to the n-type drift region 21. The first region 60a corresponds to the first region 21a. The second region 60b corresponds to the second region 21b. The structures 65 correspond to the first structures 31 and the second structures 32. The first insulating layer 71 corresponds to the field oxide film 42.

In the second step, as illustrated in FIGS. 8A and 9A, a second insulating layer 72 is formed on the second insulating layer region 71b. The second step is performed after the first step. In the second step, the second insulating layer 72 is formed, for example, only at a position where a wiring region 80b of a conductive portion 80 is formed in the seventh step. In the second step, for example, after forming the second insulating layer 72 on a whole surface of the first insulating layer 71, the second insulating layer 72 at a position where no wiring region 80b is formed is removed, and thereby the second insulating layer 72 can be left only at the position where the wiring region 80b is formed. The second insulating layer 72 is formed by, for example, the CVD or the like. The second insulating layer 72 corresponds to the etch stopper film 43.

In the third step, as illustrated in FIGS. 8A and 9A, a third insulating layer 73 is formed on the first insulating layer 71 and the second insulating layer 72. The third step is performed after the second step. The third insulating layer 73 includes a third insulating layer region 73a and a fourth insulating layer region 73b. The third insulating layer region 73a overlaps the first insulating layer 71. The third insulating layer region 73a is in contact with the first insulating layer 71. The fourth insulating layer region 73b overlaps the second insulating layer 72. The fourth insulating layer region 73b is in contact with the second insulating layer 72. The third insulating layer 73 is formed by, for example, the CVD or the like. The third insulating layer 73 functions as a mask layer used for the fourth step and the fifth step.

In the fourth step, as illustrated in FIGS. 8B and 9B, a portion of the third insulating layer region 73a and the first insulating layer region 71a is removed and a first trench TR1 is formed, and also the fourth insulating layer region 73b is removed and a second trench TR2 is formed. The fourth step is performed after the third step. In the fourth step, the first trench TR1 is formed in a portion of the third insulating layer region 73a and the first insulating layer region 71a where the electrode region 80a is formed. In addition, in the fourth step, the second trench TR2 is formed in a portion where the wiring region 80b is formed. The third insulating layer region 73a, the first insulating layer region 71a, and the fourth insulating layer region 73b are removed by, for example, etching or the like.

In the fifth step, as illustrated in FIGS. 8C and 9C, a portion of the first regions 60a overlapping the first trench TR1 is removed, and a third trench TR3 is formed. The fifth step is performed after the fourth step. In the fifth step, the third insulating layer 73 (the third insulating layer region 73a) is used as a mask and a portion of the first regions 60a overlapping the first trench TR1 (i.e., a portion not covered by the third insulating layer region 73a and the first insulating layer region 71a) is removed. The first region 60a is removed by, for example, etching or the like. Alternatively, the second insulating layer 72 may be removed after formation of the third trench TR3.

In the sixth step, as illustrated in FIGS. 8D and 9D, a fourth insulating layer 74 is formed on a bottom surface and a side surface of the third trench TR3. The sixth step is performed after the fifth step. The fourth insulating layer 74 is formed by, for example, thermal oxidation, CVD, or the like. The fourth insulating layer 74 corresponds to the gate insulating portion 41.

In the seventh step, as illustrated in FIGS. 8D and 9D, the conductive portion 80 is formed inside the third trench TR3 and inside the second trench TR2, and on the third insulating layer 73. The seventh step is performed after the sixth step. The conductive portion 80 includes an electrode region 80a, a wiring region 80b, and the removed region 80c. The electrode region 80a is located inside the third trench TR3. The wiring region 80b is located inside the second trench TR2. The removed region 80c is located on the wiring region 80b, on the third insulating layer 73, and on the electrode region 80a. The electrode region 80a corresponds to the gate electrode 13. The wiring region 80b corresponds to the wiring portion 14.

In the eighth step, as illustrated in FIGS. 8E and 9E, the removed region 80c is removed. The eighth step is performed after the seventh step. The removed region 80c is removed by, for example, CMP or the like.

According to the method described above, it is possible to easily manufacture the semiconductor device in which the width Wa of the gate electrode 13 and the width W1 of the first wiring region 14a are the same as each other. Accordingly, the semiconductor device capable of reducing the on-resistance can be easily manufactured.

As described above, according to certain embodiments, there can be provided a semiconductor device having a reduced on-resistance and a method for manufacturing a semiconductor device capable of reducing on-resistance.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first electrode;
a first semiconductor region of a first type above the first electrode, the first semiconductor region including first and second regions;
a plurality of second semiconductor regions of a second type on the first region;
a plurality of third semiconductor regions of the first type on the second semiconductor regions;
a second electrode above the third semiconductor regions and electrically connected to the third semiconductor regions;
a plurality of first structures in the first region and surrounded by the second and third semiconductor regions, each of the first structures including a first insulating region and a first conductive region inside the first insulating region, the first structures being arranged in a second direction perpendicular to a first direction from the first electrode toward the second electrode and in a third direction perpendicular to the first and second directions;
a plurality of second structures in the second region, each of the second structures including a second insulating region and a second conductive region inside the second insulating region, the second structures being arranged in the second and third directions;
a third electrode surrounding the first and second structures and extending along the second and third directions;
a first insulating portion between the second semiconductor region and the third electrode;
a second insulating portion above the second region; and
a wiring portion above the second insulating portion and electrically connected to the third electrode.

2. The semiconductor device according to claim 1, wherein
the second region includes a first portion including the second structures and a second portion around the first portion,
the wiring portion includes a first wiring region above the first portion and a second wiring region above the second portion, and
a width of the first wiring region is equal to a width of the third electrode.

3. The semiconductor device according to claim 2, wherein a width of the second wiring region is equal to the width of the third electrode.

4. The semiconductor device according to claim 1, wherein an upper surface of the third electrode is aligned with an upper surface of the wiring portion in the first direction.

5. The semiconductor device according to claim 1, wherein an upper surface of the third electrode is lower than an upper surface of the wiring portion in the first direction.

6. The semiconductor device according to claim 1, further comprising:
a third insulating portion between the wiring portion and the second insulating portion.

7. The semiconductor device according to claim 1, wherein the first region is located at a position corresponding to a center of the first electrode in the second and third directions, and the second region surrounds the first region.

8. The semiconductor device according to claim 1, wherein the first structures are surrounded by the second and third semiconductor regions on the first region.

9. The semiconductor device according to claim 1, further comprising:
a plurality of first connection portions that connect the second electrode and the second and third semiconductor regions; and
a plurality of second connection portions each connects the second electrode and a corresponding one of the first conductive regions of the first structures.

10. The semiconductor device according to claim 1, further comprising:
a reduced surface field region on the second region and surrounding one or more of the second structures.

11. A method for manufacturing a semiconductor device, the method comprising:
forming a first insulating layer on a semiconductor region of a first type including first and second regions, the first insulating layer including a first insulating layer region on the first region and a second insulating layer region on the second region;
forming a second insulating layer on the second insulating layer region;
forming a third insulating layer on the first and second insulating layers, the third insulating layer including a third insulating layer region on the first insulating layer and a fourth insulating layer region on the second insulating layer;
removing a portion of the first and third insulating layer regions to form a first trench, and removing the fourth insulating layer region to form a second trench;
removing a portion of the first region through the first trench to form a third trench;
forming a fourth insulating layer on a bottom surface and a side surface of the third trench;
forming a conductive portion in the third trench, in the second trench, and on the third insulating layer; and
removing a part of the conductive portion on the third insulating layer.

12. The method according to claim 11, wherein the first region is surrounded by the second region.

13. The method according to claim 12, wherein the first region is located at a position corresponding to a center of a surface of the semiconductor region.

14. The method according to claim 11, wherein a plurality of first structures are formed in the first region, and each of the first structures includes a first insulating region and a first conductive region inside the first insulating region.

15. The method according to claim 14, wherein a plurality of second structures are formed in the second region, and each of the second structures includes a second insulating region and a second conductive region inside the second insulating region.

16. The method according to claim 15, wherein the first and second structures are arranged in a second direction perpendicular to a first direction parallel to a surface of the semiconductor region and in a third direction perpendicular to the first and second directions.

17. The method according to claim 14, wherein the third trench is formed between the first structures.

18. The method according to claim 11, wherein the first, second, and third insulating layers are formed by chemical vapor deposition.

19. The method according to claim 11, wherein the portion of the first and third insulating layer regions is removed by etching.

20. The method according to claim 11, wherein the part of the conductive portion is removed by chemical mechanical polishing.
